(19) United States
(12) Patent Application Publication
(10) Pub. No.: US 2026/0134918 A1
(43) Pub. Date: May 14, 2026

(54) Greater than Binary State Digital Logic for Superconductive Circuits

(71) Applicant: Massachusetts Institute of Technology, Cambridge, MA (US)

(72) Inventors: Matthew GUYTON, Arlington, MA (US); Alexander WYNN, Carlisle, MA (US); Chad MEINERS, Westford, MA (US)

(73) Assignee: Massachusetts Institute of Technology, Cambridge, MA (US)

(21) Appl. No.: 18/649,419

(22) Filed: Apr. 29, 2024

Related U.S. Application Data
(60) Provisional application No. 63/510,680, filed on Jun. 28, 2023.

(51) Int. Cl. G11C 15/04; G11C 11/06; G11C 11/44; G11C 29/38

(52) U.S. Cl. CPC G11C 15/04; G11C 11/0605; G11C 11/44; G11C 29/38

(57) ABSTRACT

In some embodiments, a multistate memory cell includes; a storage loop comprising one or more superconducting devices and one or more inductive devices, the storage loop configured to maintain a quantized magnetic field representing a stored state of the multistate memory cell, the stored state from among a set of three or more distinct digital states; and at least three address lines each inductively coupled to the storage loop, wherein, in response to currents applied to the at least three address lines, the inductive couplings of the at least three address lines combine to force the quantized magnetic field to represent a particular one of the three or more distinct digital states.

### CROSS-REFERENCE TO RELATED APPLICATIONS

This application claims the benefit under 35 U.S.C. § 119 of U.S. Provisional Patent Application No. 63/510,680 filed on Jun. 28, 2023, which is hereby incorporated by reference herein in its entirety.

### STATEMENT REGARDING FEDERALLY SPONSORED RESEARCH

This invention was made with government support under FA8702-15-D-0001 awarded by the U.S. Air Force. The government has certain rights in the invention.

### BACKGROUND

Superconductor logic circuits or logic gates use the unique properties of superconductors to encode, process, and transport data. Superconductor digital logic offers the potential for processing extremely high data rates while avoiding energy density problems known to exist for CMOS digital logic. Prior superconductor circuit design has focused on binary digital logic.

### SUMMARY

As used herein, the term “multistate bit” or “multibit” refers to a unit of data that may take any of three or more distinct states or values (i.e., greater-than-two or greater-than-binary distinct states). The term “multistate digital logic” refers to a digital logic configured to store and/or operate on multistate bits.

Described herein are structures and techniques for providing multistate digital logic elements using use fewer devices (e.g., Josephson junctions, wires, etc.) than corresponding binary logic elements. Fundamental components for designing multistate digital logic for superconductive circuitry are described. Disclosed embodiments relate to structures and techniques for (1) storing multistate bits within magnetic fields (“multistate memory”); and (2) comparing the multistate bits encoded by those fields without resorting to binary digital conversion (“multistate comparators/comparison”). Also described are circuits and systems employing such structures and techniques.

By utilizing greater-than-two states, logic and memory can be more efficiently coupled for high throughput data processing. Disclosed embodiments may be used to provide data processing circuits with very high throughput (e.g., 16.8 terabits per second or higher).

The general concepts described herein utilize quantized magnetic fields within (around) superconductive materials to represent multistates for digital logic, which involves structures and techniques for setting a magnetic field to a digital (quantized) state and for comparing those digital states via constructive and destructive interference. These concepts can be used to provide addressable memory and/or logic gates to interface with other digital circuitry including but not limited to in-memory logic circuits such as content-addressable memories, or native modulo arithmetic circuitry.

According to one aspect of the present disclosure, a multistate memory cell comprises: a storage loop comprising one or more superconducting devices and one or more inductive devices, the storage loop configured to maintain a quantized magnetic field representing a stored state of the multistate memory cell, the stored state from among a set of three or more distinct digital states; and at least three address lines each inductively coupled to the storage loop, wherein, in response to currents applied to the at least three address lines, the inductive couplings of the at least three address lines combine to force the quantized magnetic field to represent a particular one of the three or more distinct digital states.

In some embodiments, different currents applied to different ones of the at least three address lines force the quantized magnetic field to represent different states. In some embodiments, the superconducting devices comprise Josephson junctions. In some embodiments, one or more of the Josephson junctions are underdamped. In some embodiments, the cell can further comprise circuitry for non-destructive readout of the stored state. In some embodiments, the circuitry for non-destructive readout comprises a readout loop inductively coupled to the storage loop.

According to another aspect of the present disclosure, a multistate memory cell comprises: one or more superconducting devices configured to maintain a quantized magnetic field representing a stored state of the multistate memory cell, the stored state from among a set of three or more distinct digital states; circuitry to increment the stored state represented by the quantized magnetic field in response a received increment pulses; and circuitry to reset the stored state represented the quantized magnetic field to a minimum state in response a received reset pulse.

In some embodiments, the circuitry to increment the stored state is configured to limit the stored state to a maximum state. In some embodiments, the superconducting devices comprise Josephson junctions. In some embodiments, one or more of the Josephson junctions are underdamped. In some embodiments, the cell further comprises circuitry for non-destructive readout of the stored state. In some embodiments, the circuitry for non-destructive readout comprises a readout loop inductively coupled to the one or more superconducting devices.

According to another aspect of the present disclosure, a content-addressable memory comprises: a plurality of search inputs each configured to receive a signal representing a state of content to be searched, the content represented by a combination of the states represented by the plurality of received signals; a plurality of multistate memory cells each configured to maintain a quantized magnetic field representing a stored state from among a set of three or more distinct digital states; and a plurality of multistate comparators each having a first input coupled to read the stored state of a respective one of the plurality of multistate memory cells, a second input coupled to one of the plurality of search inputs, the comparator configured to either pass or block a test pulse based on comparing the state of the memory cell to the state received by the search input.

In some embodiments, the plurality of search inputs comprises N search inputs, the plurality of multistate memory cells comprises an M×N array of multistate memory cells, and the plurality of multistate comparators comprises an M×N array of multistate comparators, where M>1 and N>1. In some embodiments, the memory comprises M test inputs and M test outputs, wherein each row of M multistate comparators in the array of M×N array of multistate comparators is connected in series between one of the M test inputs and one of the M test outputs. In some embodiments, a series connected row of M multistate comparators is configured to pass a test pulse from the test input to the test output based on comparing the states of each of the respective memory cells to the states received by the respective search inputs. In some embodiments, each of the plurality of multistate comparators is configured to pass the test pulse if the state of the memory cell is equal to the state received by the search input. In some embodiments, each of the plurality of multistate comparators is configured to pass the test pulse if the state of the memory cell is not equal to the state received by the search input.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is a circuit diagram showing an example of a multistate memory cell, according to some embodiments.

FIG. 1A illustrates how the state stored within a multistate memory cell can be changed.

FIG. 2 illustrates transient response of the multistate memory cell of FIG. 1 through write and read operations.

FIG. 3 is a circuit diagram showing an example of a multistate memory cell configured to increment digital state in response to pulses, according to some embodiments.

FIG. 4 is a circuit diagram showing another example of a pulse increment multistate memory cell, according to some embodiments.

FIGS. 5A and 5B are state diagrams illustrating operation of a pulse increment multistate memory cell, according to some embodiments.

FIG. 6 is a circuit diagram showing an example of a multistate comparator, according to some embodiments.

FIG. 7 is a circuit diagram showing another example of a multistate comparator, according to some embodiments.

FIG. 8 is a block diagram showing a ternary content-addressable memory (TCAM) employing multistate digital logic elements, according to some embodiments.

FIG. 9 is a block diagram illustrating a multistate random-access memory (RAM) using vortex-transitional storage cells, according to some embodiments.

FIG. 10 is a block diagram illustrating a multistate RAM using a pulse increment multistate memory cells, according to some embodiments.

The drawings are not necessarily to scale, or inclusive of all elements of a system, emphasis instead generally being placed upon illustrating the concepts, structures, and techniques sought to be protected herein.

### DETAILED DESCRIPTION

Disclosed embodiments utilize the quantized nature of the electromagnetic fields within superconductors. That is, the magnetic flux through a superconductor loop has values that are evenly divisible by a magnetic flux quantum, which is a fundamental constant. Disclosed embodiments utilize this quantization of electromagnetic field to store multiple levels of digital states that can be meaningfully compared against one another to drive other logical decisions within superconductive circuits.

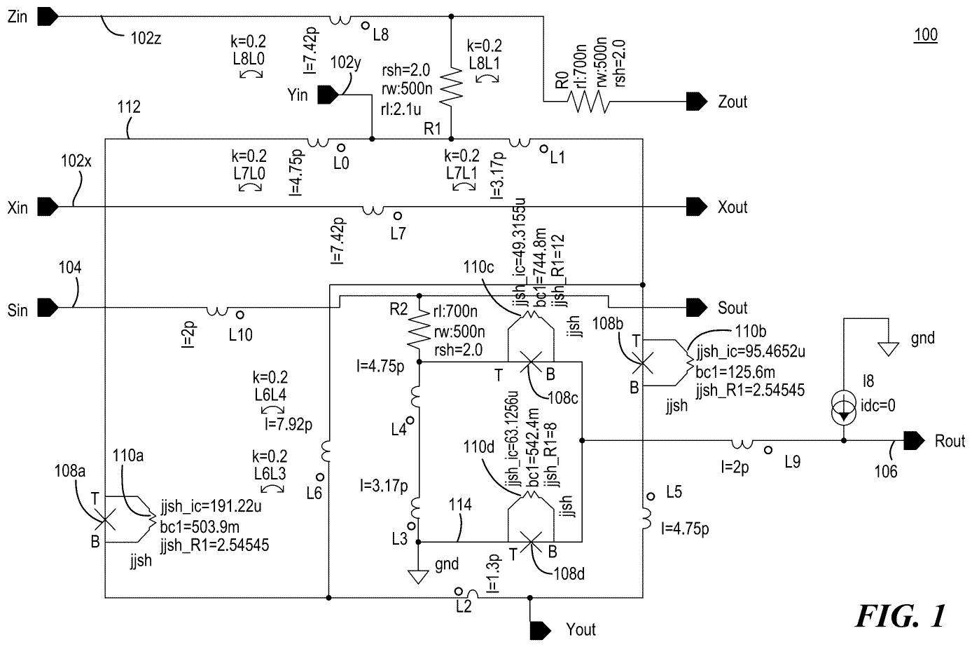

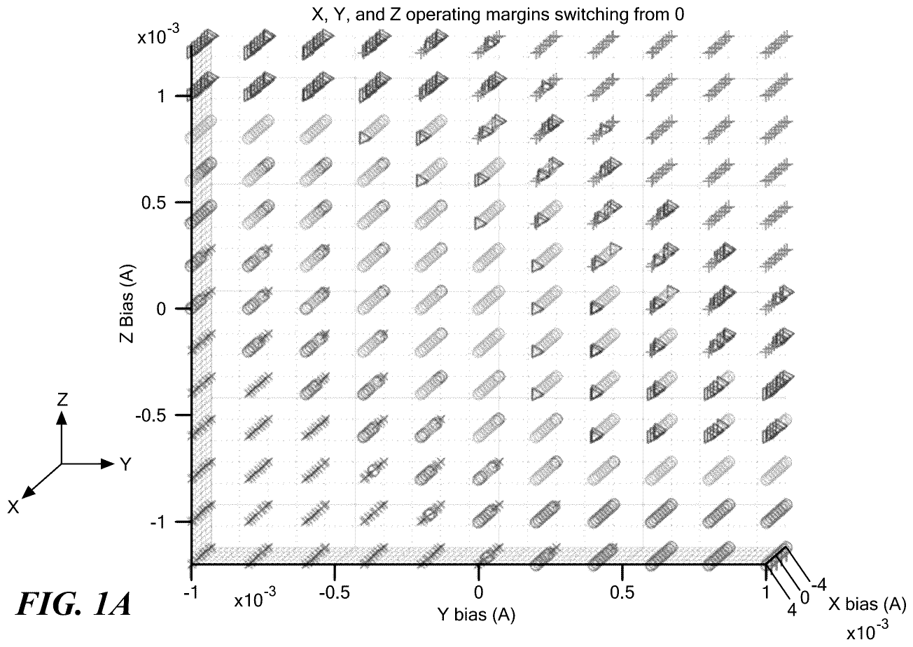

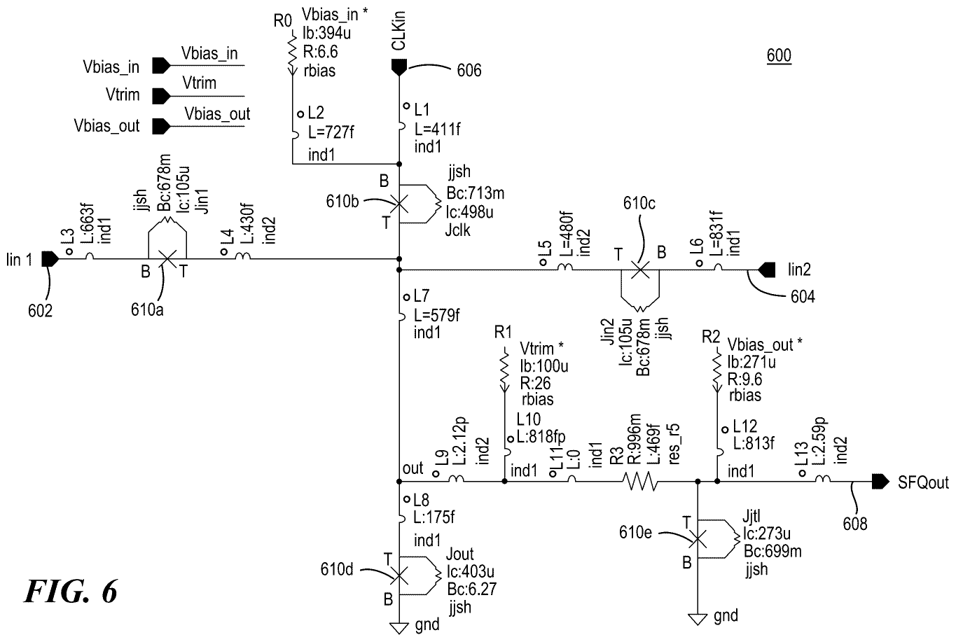

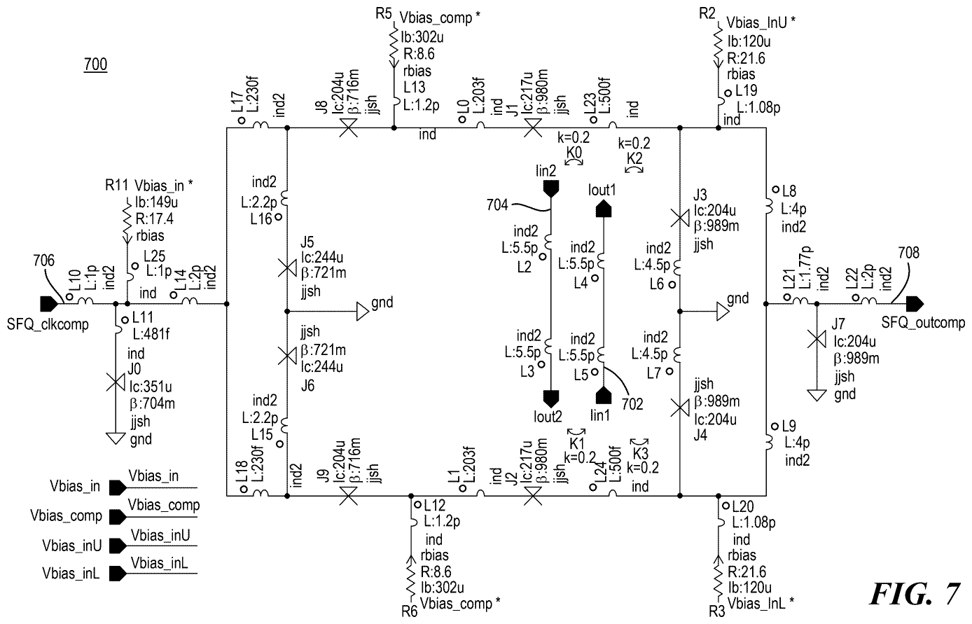

The following discussion generally relates to two fundamental classes of components/techniques for designing multistate digital logic. A first class, described in the context of FIGS. 1-5B, includes multistate memory cells (or “memory elements”) and techniques for setting multistate memory to known digital states. A second class, described in the context of FIGS. 6 and 7, includes multistate comparators for reading and comparing the digital states of the multistate memory. Also described are circuits and systems employing such components and techniques.

Various figures (e.g., FIGS. 1, 3, 4, 6, and 7) show circuits with specific parameters (e.g., sizes) denoted for certain devices (e.g., inductors). It should be understood that these parameters are merely illustrative and non-limiting, and that other circuit device parameters could be used.

Turning to FIG. 1, multistate memory can use electrical inductors/transformers to store magnetic fields. The inductance and critical current of the superconducting loop determines how many stable digital states can be stored.

FIG. 1 shows an example of a multistate memory cell 100 (sometimes referred to as a “multistate vortex transition cell”) configured to store a multistate bit using a combination of address lines (e.g., wires or other types of conductive paths) that are arranged to couple magnetic field into, or amplify the magnetic field within, a transformer that is coupled with storage inductance.

Illustrative cell 100 includes inductors L0 to L10, resistors R0 to R2, and Josephson junctions 108a-d each connected in parallel with a respective resistor 110a-d to provide damping of the junctions. Memory cell 100 also includes three address lines 102x, 102y, 102z, each with an input terminal (Xin, Yin, Zin) and a corresponding output terminal (Xout, Yout, Zout). Various terminals illustrated and described herein may correspond to pins. The various circuit elements/devices can be connected as shown in the figure. Memory cell 100 (as well as other multistate digital logic described herein) can be fabricated using any known superconducting circuit fabrication technique, such as a tri-layer process involving niobium and oxidized aluminum.

In the example of FIG. 1, a transformer is formed of the coupling between the following pairs of inductors: L8 and L0 (“L8L0”), L8 and L1 (“L8L1”), L7 and L0 (“L7L0”), and L7 and L1 (“L7L1”). Also in this example, the storage inductance is spread across inductors L5, L2 and L6, and also inductors L0, L1, plus at least a portion of the mutual inductance of the transformers from inductors L6, L0, L1. This magnetic coupling provides the energy to push/pull the storage inductor into a new stable digital state.

Memory cell 100 also includes a storage loop 112 a readout loop 114. Storage loop 112 comprises inductors L0, L1, L5, L6, and L2, and junctions 108a and 108b, with inductor L6 being arranged on a branch of the loop. Readout loop 114 comprises inductors L3 and L4 and junctions 110c and 110d. Storage loop 112 and readout loop 114 are inductively coupled together by inductor L6 of storage loop 112 and inductors L3 and L4 of readout loop 114. Address line 102x is inductively coupled to storage loop 112 by inductor L7 of line 102x and inductors L0 and L1 of storage loop 112. Address line 102z is inductively coupled to storage loop 112 by inductor L8 of line 102z and inductors L0 and L1 of storage loop 112, in addition to a direct coupling through R1.

In FIG. 1, inductive couplings, which may correspond to transformers, are represented by arcs with double-ended arrows and labeled with the magnetic coupling constants between pairs of inductors (e.g., “k=0.2” for “L8L0”). The magnetic coupling constant k can be used to calculate the mutual inductance M between a pair of inductors L1 and L2 as follows: M=k*sqrt(L1*L2). Address line 102y can be directly connected to storage loop 112 between inductors L0 and L1, as shown.

Many copies of memory cell 100 may be combined and arranged to provide multistate random-access memory (RAM) that has increased memory density compared to conventional RAM. The address lines 102x-z can be used to address a particular memory cell within the RAM for reading/writing. Whereas conventional (binary) memory typically includes only two address lines (X & Y), here a third address line (Z) is provided to allow write selection of three different states for each bit-cell without unintended overwrites occurring on adjacent cells of the same row, column, or diagonal (i.e., memory cell 100 may be configured to store a 3-state value).

In more detail, the effect of the three address lines X, Y, Z combine (via constructive interference) to force cell 100 to store a particular value. Other cells in the RAM array may be connected to two of the three address lines, but no other cell may share all three of these specific lines. Of note, the combined effect of only two address lines (e.g., X and Y, or Y and Z) would not be enough to force cell 100 into a particular state. Since the control signals are distributed across three address lines, then the state of an individual cell can be set (because it is the only cell connected to all three of these address lines).

In some cases, multiple cells 100 may be arranged in a two-dimensional array, with the X address line 102x connecting cells in the same row, the Y address line 102y connecting cells in the same column, and the Z address line 102z connecting cells along the same diagonals of the array.

Memory cell 100 also includes a sampling line 104 having an input terminal (Sin) and an output terminal (Sout), and a readout line 106 having an output terminal (Rout). Sampling line 104 can be used to sample the cell's stored value onto the readout line 106. Readout line 106 is connected to readout loop 114, collectively forming a readout circuit that allows for nondestructive cell reads (due to its magnetic coupling to storage loop 112, as previously discussed).

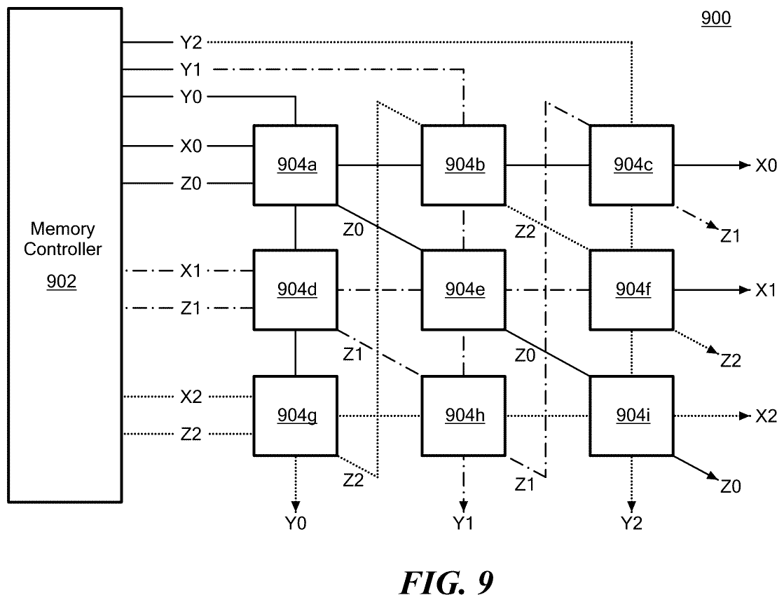

The various address lines 102x-z can be connected to a memory controller and/or address lines of other multistate memory cells. In this way, many instances of a disclosed multistate memory cell can be used to form an addressable, multistate RAM, such as described below in the context of FIG. 9.

While the memory cell illustrated in FIG. 1 may be configured to store three distinct states, the general approach illustrated and described may be used to store greater numbers of distinct states (e.g., five distinct states).

FIG. 1A illustrates how the state stored within a multistate memory cell (e.g., a cell similar to that of FIG. 1) can be changed using X, Y, and Z address lines. In this example, it is assumed that the memory cell is configured to store five distinct states: {−1, −0.5, 0, 0.5, 1}. The horizontal axis is “Y”, the vertical axis is “Z”, and the axis out of/into the page is X. From a starting state (e.g., 0), the values of current in address signals X, Y, and Z can be swept as shown. For example, from a starting state of 0, one could, for example, increase some combination of X, Y, and Z to force the state to 0.5.

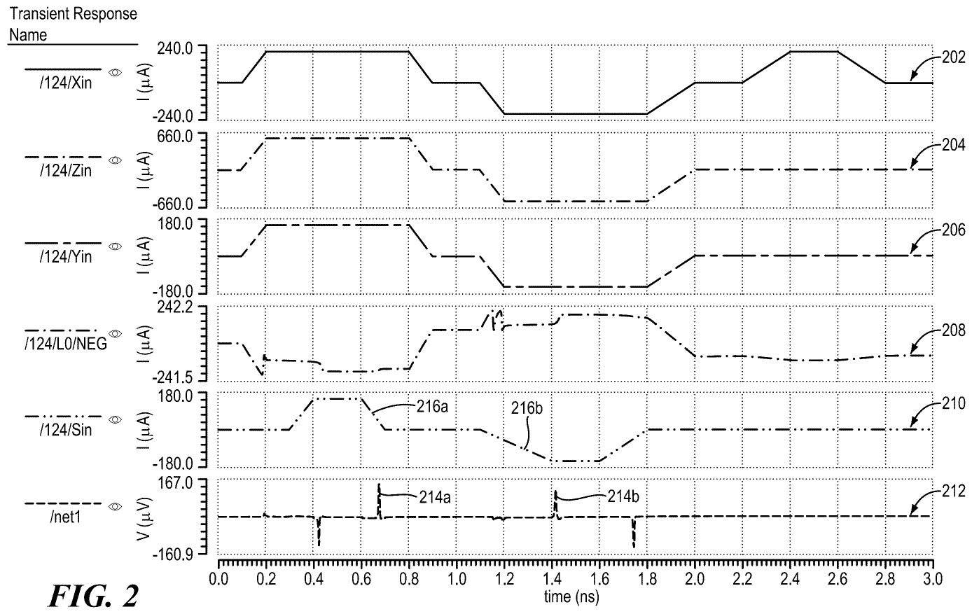

FIG. 2 illustrates transient response of the multistate memory cell of FIG. 1 through write and read operations. Multiple time series plots 202-212 are shown over the same period, with a first plot 202 representing a current applied to the X address line input terminal (Xin) over time, a second plot 204 representing current applied the Z address line input terminal (Zin) over time, a third plot 206 representing current applied to the Y address line input terminal (Yin) over time, a fourth plot 208 representing current through inductor L0 over time, a fifth plot 210 representing current at the sampling line input terminal (Sin) over time, and a sixth plot 212 representing the voltage on the output terminal (Rout) over time. Time is represented in ns, voltage in uV, and current in uA.

FIG. 2 shows ternary readout of the stored value. In this example, a value of 1 is stored and then read out. Depending on the stored state, the output terminal (Rout) will show one of: (a) a positive spike after a falling edge of Sin, on Sin's return to 0 current from positive, indicating that the stored value is positive; (b) a positive spike after a falling edge of Sin, as Sin swings to a negative amplitude, indicating that the stored value is negative; or (c) no positive spike, indicating that the stored value is zero. For example, plot 212 includes positive spikes 214a, 214b after falling edges 216a, 216b of plot 210, respectively. Of note, which direction is “positive” is arbitrary since mutual inductances can always be reversed (e.g., by mirroring the readout SQUID that Sin is connected to).

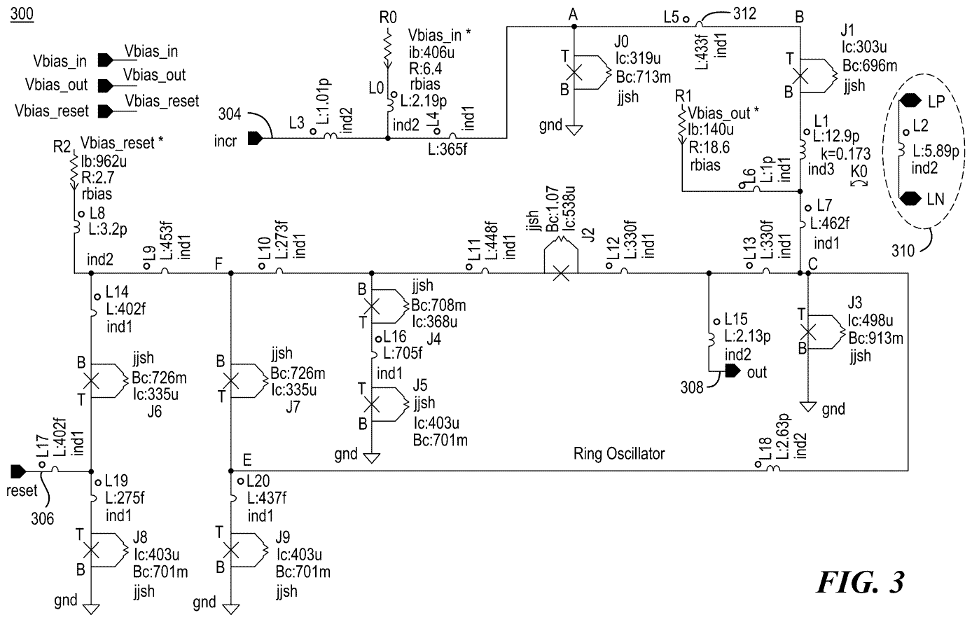

FIG. 3 shows an example of a multistate memory cell 300 configured to increment digital state in response to pulses, according to some embodiments. Memory cell 300, which may be referred to as a “pulse increment memory cell with merge/split reset,” uses a storage inductor L1 to capture and accumulate electrical flux quantum (FQ) pulses applied to an increment terminal 304 (inc), whereby each pulse increments the digital state of the memory.

Illustrative memory cell 300 includes inductors L0 to L20 (including storage inductor L1), Josephson junctions J0 to J10, resistors R0 to R2, increment terminal 304, a reset terminal 306, an output terminal 308, a readout circuit 310, a bias input terminal Vbias_in, a bias output terminal Vbias_out, and a bias reset terminal Vbias_reset, which circuit elements/devices can be connected as shown. The Vbias terminals can be used to produce an asymmetry on the Josephson junctions so that they can be used to block pulses from one direction and not the other. Vbias_in can be used to bias junctions J0 and J1 to amplify incoming pulses from increment terminal 304, and to prevent pulses from leaving increment terminal 304. Vbias_reset biases J4, J5, J6, J7, J8, and J9 for a similar function for the reset pin. Vbias_out biases junction J3 to amplify output pulses to the out pin. The threshold for maximum number of stored pulses in L1 can be controlled through adjusting Vbias_in and Vbias_out to set the difference in bias currents for J1 and J3. The threshold for the minimum number of stored pulses to retain after a reset signal is controlled by adjusting Vbias_reset and Vbias_out to set the difference in bias currents for J2 and J3.

A single pulse applied to reset terminal 306 causes memory cell 300 to return to a minimum state (e.g., the zero state), regardless of its current state. In more detail, resetting the storage inductor L1 is accomplished using a ring oscillator to circulate a decrementing pulse (pulses in the opposite direction) until the zero state is reached. In this example, the ring oscillator is formed from junctions J3, J4, J5, J7, and J9, and associated inductors L10, L11, L12, L13, L18, and L20. When a reset pulse enters the circuit at terminal 306, it circulates through this ring oscillator, repeatedly reducing the state current stored in L1 and J3 until the point when J2 has a relatively higher bias than J3, and so J2 fires, ending the circulation of the reset pulse. This configuration allows both for more efficient control (requiring only a single external pulse) and less complex control (not requiring prior knowledge of the cell's stored multistate) compared to other approaches. Moreover, the (circulated) decrementing pulses can be read out via output terminal 308, allowing for combined reset-and-read operation. This reset-and-read operation can be particularly useful if these storage cells are chained to form a shift register.

As shown, readout circuit 310 can be inductively coupled to storage inductor L1 via inductor L2 to allow for non-destructive readouts.

Junction J1 can control the maximum stored state (i.e., to limit the stored state to a maximum value regardless of the number of increment pulses received). Without this blocking junction, the count would reset (overflow) when it reaches the maximum count supported by multistate memory cell 300. More generally, the maximum storable state is set by the size of L1 and whichever junction (in this case J1) that limits the maximum current that can flow in storage loop J0, L5, J1, L1, L7, J3.

Junction J2 can control the minimum stored state during reset. If the circuit is in this minimum state, a pulse at reset terminal 306 will be blocked by J2 before it can reach J3. If there is relatively low bias current and state current flowing through J3, then when a reset pulse arrives, J2 will fire instead of J3. If there is relatively high bias current and state current flowing in J3, then when a reset pulse arrives, J3 will fire instead of J2 (kicking off a reset pulse that circulates in the ring oscillator).

Stacked junctions J4 and J5 act as one Josephson transmission line (JTL) stage while equalizing the current distribution from bias resistor R2.

The operation of memory cell 300 can be viewed as a state machine, as discussed further below.

The illustrative memory cell 300 shown in FIG. 3 may be designed to store three distinct states. However, the general approach may be scaled up to higher numbers of states by, for example, increasing the size of storage inductor L1 and possibly resizing other circuit devices. Of note, some of the inductors shown in FIG. 3 (as well as in other digital logic circuit diagrams of this disclosure) are intended to model parasitic inductances and may be omitted in some implementations. For example, some inductors shown as having a single hump, such as inductor 312, may be omitted in some implementations.

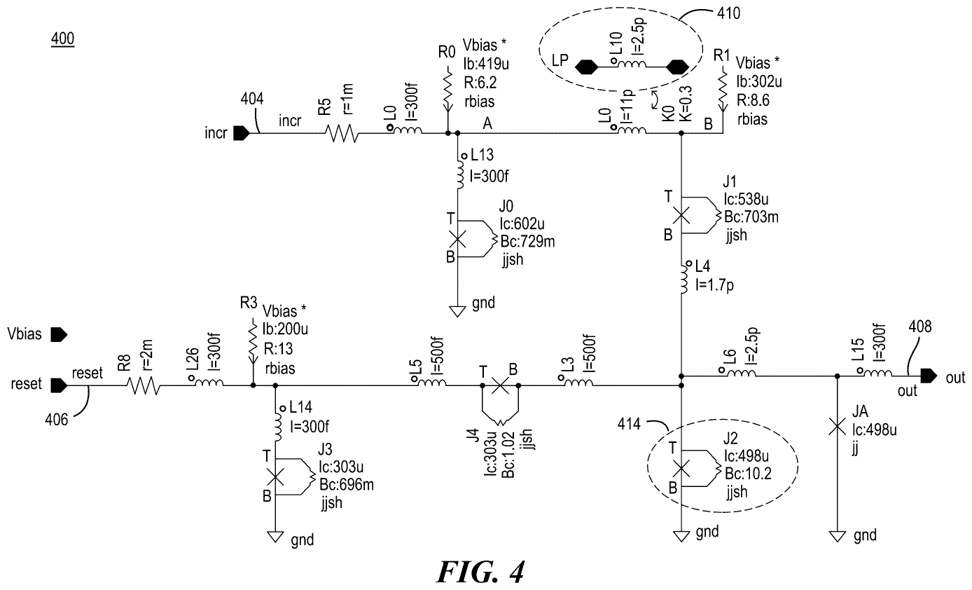

FIG. 4 shows another example of a pulse increment multistate memory cell, according to some embodiments. Illustrative memory cell 400 operates similar to memory cell 300 of FIG. 3, but replaces the reset circulating loop in FIG. 3 with an unshunted Josephson junction 414 to generate the decrementing pulses to reset the memory. Thus, cell 400 may be referred to as a “pulse increment memory cell with unshunted Josephson junction reset.” Josephson junction 414 can either be an underdamped junction (having a relatively large resistance across its terminals), or an unshunted junction (having no external resistor across its terminals). Either way, it will be appreciated that there is not enough of a conductive path across the junction. This makes it unstable, so once this junction is activated, it will continue to fire until the current through the junction decreases below some threshold (called the return current). This junction's instability has a similar functionality to the ring oscillator shown and described in the context of FIG. 3.

Memory cell 400 uses a storage inductor L1 to capture and accumulate electrical flux quantum (FQ) pulses on increment terminal 404, whereby each pulse increments the digital state of the memory. A single pulse applied to reset terminal 406 causes memory cell 400 to return to the zero state while, at the same time, the current state can be read out via output terminal 408. A readout circuit 410 is magnetically coupled to storage inductor L1 via inductor L10 to allow for non-destructive readout.

Of note, junction J1 is a blocking junction to control the highest state that can still be incremented. Junction J4 is another blocking junction, which controls the lowest state that can still be reset. When the stored state is at the reset level (e.g., 0), junction J4 fires to block extra reset pulses. It also blocks junction J2's “decrement” pulses (other than the first) from travelling back to J3. Also of note, junction J2 is an underdamped junction and its instability controls how low the stored value resets from higher states.

In the memory cell examples of FIGS. 1, 2, and 4, the storage inductor may not be a strictly linear inductor. For example, in some embodiments, the nonlinear Josephson inductance of one or several junctions in series with a linear inductor may be used.

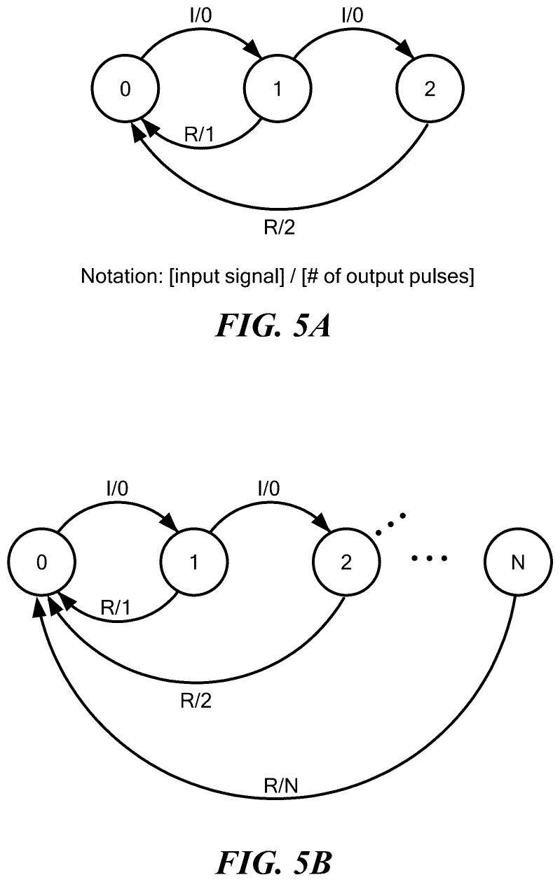

FIGS. 5A and 5B illustrate operation of a pulse increment multistate memory cell, such as cell 300 of FIG. 3 or cell 400 of FIG. 4.

FIG. 5A shows the increment and reset state transitions for cell configured to store three distinct states: {0, 1, 2}. As shown, an increment (I) pulse transitions the cell from the 0 state to the 1 state, and another increment pulse transitions it to the 2 state. No output pulses are generated during increment. A reset pulse (R) transitions the cell from the 1 state to the 0 state and generates one output pulse, or transitions the cell from the 2 state to the 0 state and generates two output pulses.

FIG. 5B shows generalized increment and reset state transitions for cell configured to store N distinct states: {0, 1, 2, . . . , N}.

One or more of the memory cell approaches disclosed herein may be adapted to allow reading out of multiple logic states. For example, three distinct logic states can be multiplexed into a single readout line using the timing of an AC (e.g., sine wave) readout clock to encode data “1” as corresponding with the alignment in time of a readout pulse with the time of positive clock amplitude, while “−1” corresponds with the alignment of a readout pulse with negative clock amplitude; state “0” corresponds to no readout pulse arrival.

Turning to FIGS. 6 and 7, next disclosed are structures and techniques for comparing the digital states of two or more multistate memory cells. For example, disclosed multistate comparators can be used to compare values stored in two instances of pulse increment multistate memory cell 300 of FIG. 3.

FIG. 6 shows an example of a multistate comparator 600, according to some embodiments. Comparator 600 includes resistors R0 to R3, inductors L0 to L13, a first input 602 (Iin1), a second input 604 (Iin2), a clock pulse input terminal 606 (CLKin), a pulse output terminal 608 (SFQout), and Josephson junctions 610a-e. Comparator 600 further includes a bias input terminal Vbias_in, a threshold adjustment current terminal Vbias_trim, and a bias output terminal Vbias_out.

Current applied to threshold adjustment current terminal Vbias_trim can be varied to either configure comparator 600 to perform either a “greater-than-or-equal” comparison or a “greater-than” comparison. In more detail, input terminals 602, 604 (Iin1, Iin2) are connected to storage circuits using opposite polarities. If the storage circuits have equivalent stored currents, then the current contributed to junction 610b (Jclk) and inductor L7 by Iin1 and Iin2 are canceled out. When a clock pulse is received via terminal 606, it will be blocked by junction 610b if more current flows down through junction 610b than through junction 610d. If less current flows down through junction 610b than through junction 610d, then instead junction 610d will fire in response to an input through terminal 606, and the clock pulse will travel out through terminal 608. The current through junction 610d in this balanced state can be increased using Vtrim. A higher Vtrim can be used to set the circuit to a “greater than or equal” mode. A lower Vtrim can be used to set the circuit to a “greater than” mode.

Current applied to bias input terminal Vbias_in sets the current flowing downward through junction 610b, which then splits, and to a lesser extent, also biasing junctions 610a, 610c, and 610d.

Current applied to bias output terminal Vbias_out sets the bias for output buffer junction 610e. In some embodiments, resistor R3 can be configured to block this bias current, simplifying the circuit by limiting bias current from Vbias_out to only affecting output buffer junction 610e.

The various circuit elements/devices can be connected as shown in the FIG.

First input 602 may be connected to a non-destructive readout of a first multistate memory multistate cell (e.g., to readout circuit 310 of FIG. 3) and second input 604 may be connected to a non-destructive readout of a second multistate memory cell. Comparator 600 uses the currents induced by the magnetic fields to both non-destructively read the storage inductors and to compare two storage inductor's digital states (performing either a “greater-than-or-equal” or a “greater-than” comparison based on the current applied to Vbias_trim). Junctions 610a and 610c block pulses from feeding backwards and affecting the flux stored in the transformer loops of the memory cells connected to respective inputs 602 and 604.

Comparison results can be signaled on output terminal 608 using single-flux quantum (SFQ) pulses. In more detail, the currents can be arranged into a push-pull configuration such that, when an electrical SFQ pulse is applied to clock terminal 606, the pulse can only pass through to output terminal 608 when the pull of one memory cell does not exceed the push from the other cell. Thus, the presence of an output pulse on terminal 608 can be interpreted as one comparison result (e.g., true or 1) and the lack of an output pulse on terminal 608 can be interpreted as the opposite result (e.g., false or 0).

FIG. 7 shows another example of a multistate comparator 700, according to some embodiments. Comparator 700 includes resistors R2, R3, R5, R6, and R11, inductors L0 to L22, junctions J0 to J8, a first input 702, a second input 704, a clock line 706, and an output line 708.

Comparator 700 further includes bias terminals Vbias_in, Vbias_comp, Vbias_inU, and Vbias_inL. Vbias_in biases input buffer J0. Vbias_comp biases blocking junctions J1 and J2 and reverse-biases junctions J8 and J9. Reverse biasing J8 and J9 can be useful as they are not meant to fire, but rather are used to symmetrically balance J1 and J2 in the bias distribution from Vbias_comp. Current flowing from Vbias_inU makes junction J3 more likely to fire than blocking junction J1. Current flowing from Vbias_inL makes junction J4 more likely to fire than blocking junction J2. In this manner, Vbias_inU and Vbias_inL are used to set the upper and lower thresholds for what is consider “not equal.” In other words, this bias can determine how much difference in current is required between the two comparator inputs, Iin1 and Iin2, in order for either J3 or J4 to fire. Output buffer J7 logically ORs the pulses from J3 and J4 and sends them to output port 708. If the difference between currents Iin1 and Iin2 are greater than some upper threshold, or less than some lower threshold, then the two state currents are not equal.

The various circuit elements/devices can be connected as shown in the FIG.

In this example, comparator 700 is configured to perform a “not equals” comparison on the state of a first multistate memory cell connected to first input 702 and the state of a second multistate memory cell connected to second input 704, using a SFQ pulsing scheme similar to that described above for FIG. 6.

The illustrative comparator 700 uses a destructive transformer, that is, the current flow in the two inductors oppose each other, to either generate no magnetic field when the memory cells are in the same digital state, or it generates a magnetic field when the memory are in different digital states. Comparator 700 uses this destructive transformer to block pulses between clock line 706 and output line 708 when there is no magnetic field generated from the transformer. In more detail, if the digital state of the first memory cell is greater than the state of the second cell, then a pulse will travel along the top path of the circuit to output line 708. If the state of the second cell is larger, then the pulse will travel along the bottom path of the circuit to output line 708. Otherwise, if the states are equal, the pulse will be blocked. By combining both “less-than” and “greater-than” operations, comparator 700 determines whether two stored states are “not equals.”

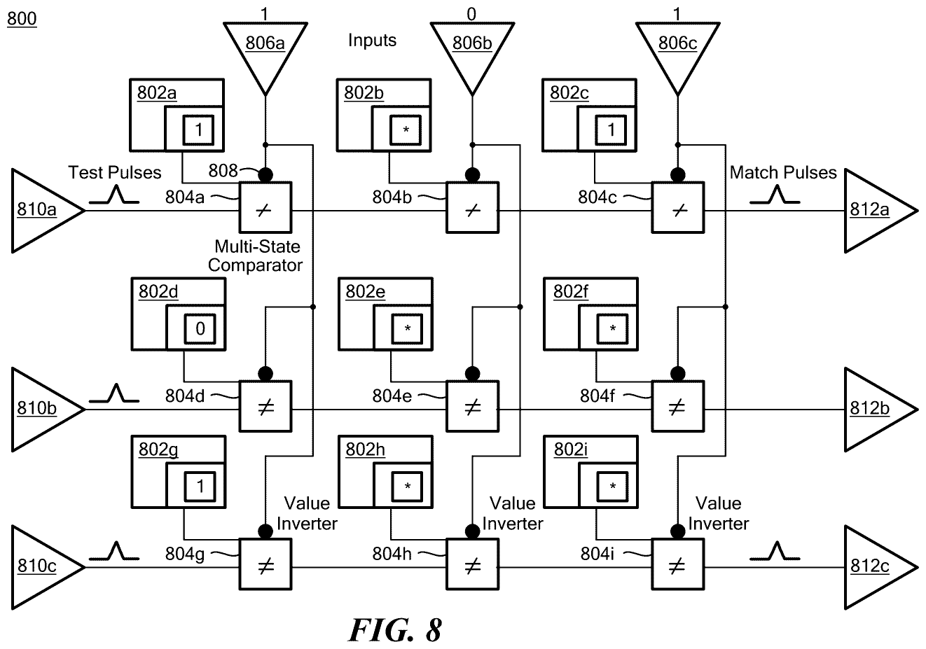

It will be appreciated that general concept illustrated in FIG. 7 can be used to provide an “equals” comparator, blocking the pulse if the two multibit states are not equal. For example, one of the multistate inputs can be inverted, such as illustrated in FIG. 8.

While FIGS. 6 and 7 show examples of comparison circuits for comparing two memory cells, the general structures and techniques disclosed herein can be used for comparing greater numbers of cells. For example, equivalent operations can be performed to compare the series or parallel sums or differences of currents from three or more multistate memory cells. Moreover, a skilled artisan will appreciate the digital comparator elements disclosed herein can be arranged and combined in various ways to build higher-order digital logic elements and, in turn, can provide the basis for a greater-than-binary computer.

FIG. 8 is a block shows an example of a ternary content-addressable memory (TCAM) 800 employing multistate digital logic elements, according to some embodiments. TCAM is a specialized type of high-speed memory that can search its entire contents in a single clock cycle, where the contents are a sequence of pattern strings comprised of multibit states from the set {0, 1, *}, where * corresponds to a wildcard (i.e., matches either 0 or 1). In some cases, the multibit states may be from the set {0, 0.5, 1} where 0.5 corresponds to the wildcard.

Illustrative memory 800 includes a plurality of multistate memory cells 802a-i (802 generally) and a plurality of multistate comparators 804a-i (804 generally). In the example of FIG. 8, nine (9) multistate memory cells 802 and nine (9) multistate comparators 804 are shown, however other numbers of cells and comparators can be provided. Each of memory cells 802 may be the same as or similar to the multistate memory cell of FIG. 1, 3, or 4. In the example of FIG. 8, comparators 804 are configured to perform a “not equals” comparison and thus may be the same as or similar to the not-equals comparator of FIG. 7. To enable TCAM 800 to match on a given input string, one input of each comparator 804 may be inverted using a value inverter (denoted by block circles in the figure, e.g., value inverter 808) changing the “not equals” comparison to an “equals” comparison. When the comparator of FIG. 7. is used, implementing the value inverter does not require additional circuitry, instead the input value line can be swapped between Iin2 and Iout2, or Iin1 and Iout1 in FIG. 7. Thus, illustrative value inverter 808 can simply reverse the direction of that input's current through the comparator. The input is a current that flows from one terminal, i.e. Iin1, to another, Iout1.

The multistate memory cells 802 can be arranged in M rows each having N cells (columns). Thus, each row can be programmed to store a string of N multibit states (e.g., using structures and techniques described above with FIGS. 1-4). In the example of FIG. 8, M=N=3, with a first row comprised of cells 802a-c, a second row comprised of cells 802d-f, and a third row comprised of cells 802g-i. The general concepts disclosed herein can be used to form a TCAM having an arbitrary number of rows and columns (e.g., M and N can be varied based on application requirements or other factors).

Each multistate memory cell 802a-802i is connected to one input of a respective one of the multistate comparators 804a-804i, as shown. These connections may correspond to non-destructive readout lines, as previously discussed. The other input of each comparator 804 is connected to a given one of N search inputs 806a-c (806 generally). In more detail, comparators 804a,d,g in a first column are connected to a first search input 806a, comparators 804b,e,h in a second column are connected to a second search input 806b, and comparators 804c,f,i in a third column are connected to a third search input 806c. In this way, a first value provided at first search input 806a is compared to the first multibit state stored in each of the M rows, a second value provided at second search input 806b is compared to the second multibit state stored in each of the M rows, and a third value provided at third search input 806c is compared to the third multibit state stored in each of the M rows. The number of search inputs 806 can increase or decrease with N.

The values (e.g., currents or voltages) provided at search inputs 806 may be binary, meaning they have a state from the set {0,1}. In contrast, the states stored in memory cells 802 may be ternary, meaning they have a state from the set {0, 0.5, 1}, for example, where 0.5 is used as a wildcard. In this way, TCAM 800 can perform searches using input strings provided by binary digital logic (e.g., by a conventional binary computer).

As previously discussed, a multibit comparator can block (or not block) an SFQ pulse applied its clock line from passing through its output line based on the states of the two multistate cells being compared. Thus, to test if an input string of length N (provided at search inputs 806a) matches each of the strings of length N stored the M rows of memory cells, each row of comparators can be connected in series. In more detail, using the first row of comparators 804a-c as an example, comparator 804a can have its clock line connected to a test input terminal 810a, comparator 804b can have its clock line connected to the output line of comparator 804a, comparator 804c can have its clock line connected to the output line of comparator 804b, and the output line of comparator 804c can be connected to a test output terminal 812a. A pulse applied to test input terminal 810a reaches test output terminal 812a only if the input string matches the states of multistate cells 802a-c. Likewise, the second row of comparators 804d-f can be connected serially between test input terminal 810b and test output terminal 812b, and the third row of comparators 804g-i can be connected serially between test input terminal 810c and test output terminal 812c.

Thus, TCAM 800 matches an input string to M stored strings (i.e., the entire contents of memory) in a single clock cycle when SFQ pulses are simultaneously applied to the M test input terminals 810a-c. In the example of FIG. 8, the first row of multistate memory cells stores the string 1*1, the second row stores the string 0**, and the third rows stores 1** (where * is the wildcard matching on either 0 or 1). The input string is 101. Thus, as shown, TCAM 800 produces pulses at test output terminals 812a and 812c but not at test output terminal 812b.

The pulses produced at test output terminals 812a-c can be processed using conventional digital or analog circuitry. For example, an output pulse (or lack thereof) can be converted to a binary value and transmitted on a data bus of a conventional digital computer.

Implementing a ternary content-addressable memory using multistate digital logic reduces the number of circuit elements/devices compared to a using binary digital logic. For example, the number of comparators and the number of memory cells may be reduced by half. Other advantages to a TCAM based on superconducting logic (e.g., Single Flux Quantum logic) include: significant speed increase, such as the ability to clock at 10-20× faster than CMOS logic; less heat dissipation compared to CMOS (at least where logical operations are being performed), allowing for increased density without overheating; and simplified system design, due to the use of logic that is inherently ternary.

FIG. 9 shows an example of a multistate random-access memory (RAM) 900, according to some embodiments. Illustrative RAM includes a vortex transitional memory controller 902 and a plurality of multistate memory cells 904a-i (904 generally). Each of the multistate memory cells 904 may correspond to a vortex-transitional storage cell, such as shown and described with FIG. 1. Each cell 904 can be addressed by three lines—X, Y, and Z—connected to controller 902. As shown in FIG. 9, the cells 904 may be arranged as a matrix, with an X address line connecting cells in each row (X0, X1, X2, etc.), a Y address line connecting cells in each column (Y0, Y1, Y2, etc.), and a Z address line connecting cells along diagonals (Z0, Z1, Z2, etc.). While only nine (9) cells 904 are shown in FIG. 9, the general concept described can be extended to an arbitrary number of multistate memory cells.

Controller 902 can write to an individual cell 904 using a unique combination of X, Y, and Z address lines. In more detail, controller 902 can generate signals (e.g., current signals) on a particular combination of X, Y, and Z address lines to force an individual cell 904 to store a particular state via constructive interference of the X, Y, and Z address lines within the cell.

Different approaches can be used to read out the current values of RAM 900. For example, when performing a less than, greater than, or equal to comparisons on a whole word at once (e.g., a whole row of cells), the currents from each cell output can be summed. In some cases, readout SQUIDs (superconducting quantum interference devices) can be DC biased for signal amplification before sending the summed signal into a comparator. As another example, a sine wave can be used to trigger DC SQUID amplifiers in each row/column/diagonal, which will send out time-encoded SFQ pulses that can be used to identify the values at each cell by alignment with the rising of falling edge of a clock signal for 1 or −1, or absence of a pulse=0. In either case, the readout lines can be connected to the cell outputs in X, Y, or Z topologies such as illustrated in FIG. 9. While only one line is needed, splitters may be used at each cell to connect to multiple readout topologies if desirable. For example, this can be done to run two checks simultaneously: check that all least significant bits (LSBs) have a particular value (e.g., 0) using the Y line while also checking that the words themselves are greater than some other value (e.g., binary 100100) using the X line.

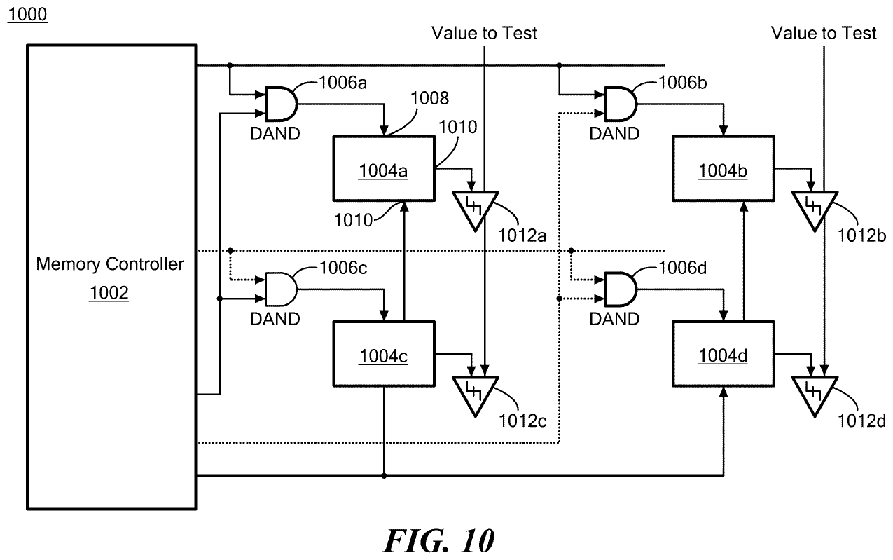

FIG. 10 is a block diagram illustrating a multistate RAM 1000 using a pulse increment multistate memory cells, according to some embodiments. Illustrative RAM 1000 includes a memory controller 1002 connected to a plurality of pulse increment multistate memory cells 1004a-d (1004 generally) via respective ones of a plurality of DAND (dynamic AND) gates 1006a-d (1006 generally). In more detail, the input of an AND gate 1006 can be connected to two address lines and the output of the AND gate 1006 can be connected to an increment terminal of a memory cell (e.g., increment terminal 1008 of cell 1004a). Each cell 1004 can also include a reset terminal (e.g., reset terminal 1010 of cell 1004a) connected to an address line or to an output of another cell. Each of the memory cells 1002 may be the same as or similar to the memory cell illustrated in FIG. 3 or FIG. 4.

A DAND gate is a superconductor logic gate that performs a logical AND function. Each DAND gate 1006 has two inputs. If a pulse enters the first input close in time to when a pulse enters the second input, then a pulse is generated at the output of the DAND gate. In the example of FIG. 10, if a row having a storage cell 1004 is activated at the same time as the corresponding column is activated, then that particular storage cell receives the signal to increment its stored value. This is one approach to using (row, column) addresses to activate a specific storage cell.

The topology of FIG. 10 may be used for row/column addressing. In other examples, values can be loaded as a shift register, writing values into column 1, and then shifting the whole memory one column at a time to the right.

As shown, comparators 1012a-d can be connected to outputs of respective memory cells 1004a-d to provide a TCAM, similar in operation to TCAM 800 of FIG. 8.

These general concepts disclosed herein can be used to provide addressable memory and/or logic gates to interface with other digital circuitry including but not limited to in-memory logic circuits such as content-addressable memories, or native modulo arithmetic circuitry.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. A multistate memory cell comprising:
a storage loop comprising one or more superconducting devices and one or more inductive devices, the storage loop configured to maintain a quantized magnetic field representing a stored state of the multistate memory cell, the stored state from among a set of three or more distinct digital states; and
at least three address lines each inductively coupled to the storage loop, wherein, in response to currents applied to the at least three address lines, the inductive couplings of the at least three address lines combine to force the quantized magnetic field to represent a particular one of the three or more distinct digital states.

2. The multistate memory cell of claim 1 wherein different currents applied to different ones of the at least three address lines force the quantized magnetic field to represent different states.

3. The multistate memory cell of claim 1 wherein the superconducting devices comprise Josephson junctions.

4. The multistate memory cell of claim 3 wherein one or more of the Josephson junctions are connected in parallel with a resistor.

5. The memory cell of claim 1 comprising circuitry for non-destructive readout of the stored state.

6. The memory cell of claim 5 where the circuitry for non-destructive readout comprises a readout loop inductively coupled to the storage loop.

7. A multistate memory cell comprising:
one or more superconducting devices configured to maintain a quantized magnetic field representing a stored state of the multistate memory cell, the stored state from among a set of three or more distinct digital states;
circuitry to increment the stored state represented by the quantized magnetic field in response a received increment pulses; and
circuitry to reset the stored state represented the quantized magnetic field to a minimum state in response a received reset pulse.

8. The multistate memory cell of claim 7 wherein the circuitry to increment the stored state is configured to limit the stored state to a maximum state.

9. The multistate memory cell of claim 7 wherein the superconducting devices comprise Josephson junctions.

10. The multistate memory cell of claim 9 wherein one or more of the Josephson junctions are underdamped.

11. The memory cell of claim 7 comprising circuitry for non-destructive readout of the stored state.

12. The memory cell of claim 11 where the circuitry for non-destructive readout comprises a readout loop inductively coupled to the one or more superconducting devices.

13. A content-addressable memory comprising:
a plurality of search inputs each configured to receive a signal representing a state of content to be searched, the content represented by a combination of the states represented by the plurality of received signals;
a plurality of multistate memory cells each configured to maintain a quantized magnetic field representing a stored state from among a set of three or more distinct digital states; and
a plurality of multistate comparators each having a first input coupled to read the stored state of a respective one of the plurality of multistate memory cells, a second input coupled to one of the plurality of search inputs, the comparator configured to either pass or block a test pulse based on comparing the state of the memory cell to the state received by the search input.

14. The content-addressable memory of claim 13 wherein the plurality of search inputs comprises N search inputs, the plurality of multistate memory cells comprises an M×N array of multistate memory cells, and the plurality of multistate comparators comprises an M×N array of multistate comparators, where M>1 and N>1.

15. The content-addressable memory of claim 14 comprising M test inputs and M test outputs, wherein each row of M multistate comparators in the array of M x N array of multistate comparators is connected in series between one of the M test inputs and one of the M test outputs.

16. The content-addressable memory of claim 15 wherein a series connected row of M multistate comparators is configured to pass a test pulse from the test input to the test output based on comparing the states of each of the respective memory cells to the states received by the respective search inputs.

17. The content-addressable memory of claim 13 wherein each of the plurality of multistate comparators is configured to pass the test pulse if the state of the memory cell is equal to the state received by the search input.

18. The content-addressable memory of claim 13 wherein each of the plurality of multistate comparators is configured to pass the test pulse if the state of the memory cell is not equal to the state received by the search input.

19. The content-addressable memory of claim 13 wherein one or more of the plurality of multistate memory cells is configured to maintain the quantized magnetic field using Josephson junctions.
